(19) United States
(12) Patent Application Publication
(10) Pub. No.: US 2016/0096962 A1
(43) Pub. Date: Apr. 7, 2016

(54) METHOD AND COMPOSITION FOR PROTECTING AN ELECTRONIC CIRCUIT BOARD FROM CONTAMINATION AND CORROSION

(71) Applicant: Foresite, Inc., Kokomo, IN (US)

(72) Inventor: Terry L. Munson, Kokomo, IN (US)

(21) Appl. No.: 14/875,790

(22) Filed: Oct. 6, 2015

Related U.S. Application Data
(60) Provisional application No. 62/060,069, filed on Oct. 6, 2014.

(51) Int. Cl. C09D 5/08; C08K 5/05; H05K 3/28; C09D 193/04

(52) U.S. Cl. CPC C09D 5/08; C09D 193/04; C08K 5/05; H05K 3/282

(57) ABSTRACT

A method for protecting an electronic circuit board by covering the board with a composition comprising rosin and a carrier and allowing the composition to dry. The coating may be provided by spraying over all or selected parts of an assembled board, or as an underfill by microdispensing under one or more components.

The rosin-containing composition may include 20% to 95% rosin and 5% to 80% of a carrier, although 30% to 80% rosin and 20% to 70% carrier, or even 30% to 50% rosin and 50% to 70% carrier, may be more preferred.

The carrier may be an alcohol, such as isopropyl alcohol, and should be free of flux activators.

### CROSS-REFERENCE TO RELATED APPLICATIONS

This application claims the benefit of U.S. Provisional Patent Application Ser. No. 62/060,069, filed Oct. 6, 2014, the entire contents of which are hereby incorporated herein by reference.

### BACKGROUND TO THE INVENTION

Conformal coatings are applied to electronic circuitry to protect against moisture, dust, chemicals, and other environmental hazards. Such coatings are typically made from acrylic resin, epoxy resin, urethane resin, or silicone resin. However, as electronic hardware is used in increasingly harsh environments, the failure rate of known coatings has not been satisfactory.

Rosin flux compositions are known to be useful for soldering components to a circuit board. Such flux compositions comprise rosin and one or more flux activators to provide an unoxidized, wettable metal surface that is suitable for the soldering process. As with solder fluxes generally, these rosin flux compositions are applied to electronic components before or during the mounting process.

A need continues to exist for improved coatings to protect electronic circuitry from the adverse effects of moisture, dust, chemicals, and other environmental hazards. The present invention addresses that need.

### SUMMARY OF THE INVENTION

One aspect of the present invention provides methods for protecting an electronic circuit board. The method comprises applying a composition comprising rosin and a carrier to an assembled board, or to components mounted on a board, and subsequently allowing the composition to dry. When dry, the rosin provides a protective barrier over and around the board and/or selected components.

In some embodiments the method comprises providing the rosin-containing composition as a protective coating over all or selected parts of the surface of a board. In these embodiments the rosin-containing composition is applied over and between the various electronic components, preferably by spraying.

In other embodiments the method comprises providing the rosin-containing composition as an underfill to a mounted electronic component. In these embodiments the rosin-containing composition is applied under one or more electronic components, preferably by microdispensing.

In the preferred embodiments the rosin-containing composition comprises 20% to 95% rosin and 5% to 80% of a carrier. More preferably the rosin-containing composition comprises 30% to 80% rosin and 20% to 70% carrier, with rosin-containing compositions comprising 30% to 50% rosin and 50% to 70% carrier being most preferred for certain applications.

The carrier may comprise or consist essentially of an alcohol, and may preferably comprise or consist essentially of isopropyl alcohol.

A second aspect of the present invention provides compositions that are effective for use on the inventive methods. The rosin-containing compositions may comprise 20% to 95% rosin and 5% to 80% of a carrier, and are free of the corrosive activators that are commonly present in rosin fluxes. More preferably the rosin-containing compositions may comprise 30% to 80% rosin and 20% to 70% carrier, or 30% to 50% rosin and 50% to 70% carrier.

### DESCRIPTION OF PREFERRED EMBODIMENTS

For the purposes of promoting an understanding of the principles of the invention, reference will now be made to certain embodiments and specific language will be used to describe the same. It will nevertheless be understood that no limitation of the scope of the invention is thereby intended, with such alterations and modifications to the illustrated device being contemplated as would normally occur to one skilled in the art to which the invention relates.

As indicated above, one aspect of the present invention provides methods for protecting an electronic circuit board. These methods generally comprise applying a composition comprising or consisting essentially of a rosin-containing material and a carrier to an assembled board, or to components mounted on a board, and subsequently allowing the composition to dry. When dry, the rosin provides a protective barrier over and around the board and/or selected components.

In some embodiments the method comprises providing the rosin-containing composition as a protective coating over all or selected parts of the surface of a board. In these embodiments the rosin coating composition is applied over and between the various electronic components, preferably by spraying.

In other embodiments the method comprises providing the rosin-containing composition as an underfill to a mounted electronic component. In these embodiments the rosin-containing composition is applied under one or more electronic components, preferably by microdispensing.

Regardless of whether the composition is being used as an over-coating or an underfill, the preferred rosin-containing compositions comprise or consist essentially of 20% to 95% rosin and 5% to 80% of a carrier. More preferably the rosin-containing compositions comprise or consist essentially of 30% to 80% rosin and 20% to 70% carrier, with rosin-containing compositions comprising or consisting essentially of 30% to 50% rosin and 50% to 70% carrier being particularly preferred for certain applications.

The carrier may comprise or consist essentially of an alcohol. In one preferred embodiment the alcohol carrier/solvent comprises or consists essentially of isopropyl alcohol.

The rosin-containing compositions are preferably free from corrosive activators. These activators are commonly found in rosin fluxes, but should be avoided in the present invention.

The coating may be applied to all or part of a circuit board. In some embodiments the entire board is coated after all of the processing work is complete. In other embodiments only selected portions of the board are coated after the components desired to be protected are mounted on the board.

The coating may be applied by spraying all or part of the board after the components to be protected have been mounted to the board. Alternatively, other methods of applying the coating may be used.

Regardless of the method of application, the rosin-containing composition is preferably provided in a formulation that allows complete coverage over the board and its components. This may include coverage over and around all of the components, including the space between the board and components mounted close to the board. To accomplish this it is preferred to use a rosin-containing composition that flows easily enough to be attracted to the space under closely-mounted components by capillary energy

As used herein, “rosin” means a solid form of resin obtained from plants, typically conifers, produced by heating fresh liquid resin to vaporize the volatile liquid terpene components. Gum rosin (from pine tree oleoresin), wood rosin (obtained by extraction of tree stumps), and tall oil rosin (obtained from tall oil, a byproduct of the kraft paper process), and/or clarified esters obtained from such rosins, may be used as desired.

One preferred rosin comprises or consists essentially of a chemical of the formula:

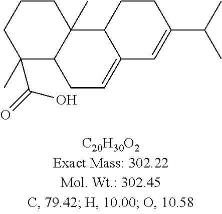 [SMILES: CC(C)C1=CC2=CCC3C(C)(C(=O)O)CCCC3(C)C2CC1]

One step in the preferred inventive process is to assemble or provide an electronic circuit board assembly. As is known to the art such circuit board assemblies may be printed circuit board assemblies, and may include functional components such as BGAs, QFNs, LCCs, diodes, resistors, and connectors.

After the circuit board is assembled or provided, the inventive protective coating is applied. In one embodiment the coating is applied by brushing, dipping or spraying the board with the coating composition. The coating is preferably applied to provide a dried or cured coating layer that is 1 mil to 5 mils thick.

The coated board is then dried (e.g., air dried) or cured. The drying or curing step may be done at an elevated temperature. In one preferred embodiment a fully processed board is sprayed with a thin layer of coating and cured at about 85° C. for about 15 minutes to create a sealed and encapsulated condition that becomes an organic barrier between the active circuits and the outside environment.

The inventive process is preferably used to treat or protect an entire board, including substantially all of the exposed surface(s) of the board. In other embodiments the inventive process may be used to treat or protect only selected portions of an electric circuit board.

Repair of a component that has been protected by the inventive coatings and processes is easy since solder can be applied or removed through the coating.

The inventive process provides a barrier against environmental contamination and/or corrosive residues. In particular, the inventive process may provide a barrier against one or more of environmental moisture, sulfur gasses, chlorine gasses, and bromide gasses. Additionally or alternatively, the inventive process may provide a barrier that binds up fabrication and assembly residues and reduces or eliminates their impact on electronic circuit performance.

To test the inventive coatings and processes modeling clay was provided on the surface of two fully processed circuit boards. One board was a control and did not have the inventive coating applied. The other board was a test board that did have the inventive coating applied. Both boards were heated in a 70° C. oven in a sulfur rich environment. Copper sulfide corrosion appeared on exposed copper and silver surfaces of the untreated (control) board. Copper sulfide corrosion did not appear on any exposed copper and silver surfaces of the treated (test) board.

Another embodiment of the inventive method comprises providing the rosin coating composition as an underfill to a mounted electronic component. In these embodiments the rosin coating composition is applied under an electronic component, preferably by microdispensing.

While the invention has been illustrated and described in detail in the foregoing description, the same is to be considered as illustrative and not restrictive in character, it being understood that only certain preferred embodiments have been shown and described and that all changes and modifications that come within the spirit of the invention are desired to be protected. In addition, it is to be appreciated that the present invention may comprise or consist essentially of any or all of the illustrated or described elements and/or features, and may comprise or consist essentially of any combination of the disclosed elements and/or features.

1. A method for protecting an assembled circuit board, comprising applying a rosin-containing composition comprising rosin and a carrier to components assembled on a board and subsequently allowing the composition to dry.

2. The method of claim I wherein the rosin-containing composition is applied as a protective coating over all parts on the surface of an assembled board.

3. The method of claim 1 wherein the rosin-containing composition is applied by spraying.

4. The method of claim 1 wherein the rosin-containing composition is applied as an underfill under a mounted electronic component.

5. The method of claim 5 wherein the rosin-containing composition is applied by microdispensing.

6. The method of claim 1 wherein said rosin-containing composition comprises 20% to 95% rosin and 5% to 80% solvent.

7. The method of claim 6 wherein said rosin-containing composition comprises 30% to 70% rosin and 30% to 70% solvent.

8. The method of claim 7 wherein said rosin-containing composition comprises 30% to 50% rosin and 50% to 70% solvent.

9. The method of claim I wherein said carrier comprises an alcohol.

10. The method of claim 1 wherein said carrier comprises isopropyl alcohol.

11. The method of claim 1 wherein said rosin-containing composition is free of flux activators.

12. The method of claim 1 wherein said board is a fully assembled circuit board.

13. A method for protecting an assembled circuit board, comprising applying a rosin-containing composition consisting essentially of rosin and a carrier to components assembled on a board and subsequently allowing the composition to dry.

14. A composition effective for protecting an electronic circuit board from corrosion, the composition comprising 20% to 95% rosin and 5% to 80% of a carrier in a formulation effective for coating and protecting an electronic circuit board from corrosion.

15. A composition according to claim 13 wherein the composition comprises 30% to 70% rosin and 30% to 70% carrier.

16. A composition according to claim 13 wherein the composition comprises 30% to 50% rosin and 50% to 70% carrier.

17. A composition according to claim 13 (herein the composition consists essentially of a rosin-containing composition and a carrier.

18. The method of claim 13 wherein said carrier comprises an alcohol.

19. The method of claim 17 wherein said carrier comprises isopropyl alcohol.

20. A composition according to claim 13 wherein the composition is free of flux activators.
